(19) United States
(12) Patent Application Publication
(10) Pub. No.: US 2015/0008985 A1
(43) Pub. Date: Jan. 8, 2015

(54) OSCILLATOR AND PHASE-LOCKED LOOP CIRCUIT

(71) Applicant: LAPIS Semiconductor Co., Ltd., Yokohama (JP)

(72) Inventor: Takashi KURAMOCHI, Yokohama (JP)

(73) Assignee: LAPIS SEMICONDUCTOR CO., LTD., Yokohama (JP)

(21) Appl. No.: 14/321,668

(22) Filed: Jul. 1, 2014

(30) Foreign Application Priority Data
Jul. 2, 2013 (JP) 2013-138945

(51) Int. Cl. H03L 7/08; H03B 7/14

(52) U.S. Cl. CPC H03L 7/08; H03B 7/14
USPC 331/25; 331/117 R

(57) ABSTRACT

An oscillator comprising: an oscillator circuit element having a substrate terminal group and a capacitance section provided on an element substrate, the substrate terminal group comprising at least three substrate terminals including a first substrate terminal and a second substrate terminal, the capacitance section being connected between the first and second substrate terminals; a mount part including an external terminal group comprised of at least one external terminal and mounting thereon the oscillator circuit element; a plurality of inductance lines which are formed among the at least three substrate terminals by conductor wirings which connect between the at least three substrate terminals of the substrate terminal group and the at least one external terminal; and a switch circuit provided on the element substrate to control a connection state of the plurality of inductance lines.

### BACKGROUND OF THE INVENTION

1. Field of the Invention

The present invention relates to a phase-locked loop and more particularly, to an oscillator used in the phase-locked loop.

2. Background Art

The phase-locked loop circuit (hereafter referred to as the PLL) is an oscillator circuit which produces and outputs a signal in synchronism with an input signal that serves as a reference signal. The PLL has, for example, a voltage controlled oscillator (hereafter referred to as the VCO) which outputs a periodic oscillation signal in accordance with an input voltage. The PLL makes a comparison between the input signal and the oscillation signal and provides control so that the input signal and the oscillation signal outputted by the VCO are synchronized in phase with each other. The PLL then outputs the synchronized signal. The VCO is comprised of a capacitive element such as a capacitor and an inductive element such as a coil.

In Japanese Patent Application Laid-Open No. 2003-60435, an LC circuit with a protective element coupled to the midpoint of the coil of an LC oscillator circuit as well as a PLL that employs the LC circuit are disclosed. In Japanese Patent Application Laid-Open No. 2002-75735, an inductor element is disclosed which includes bonding pads arranged in a matrix, pattern sides for connecting between the bonding pads, and bonding wires for connecting between any two bonding pads. In Japanese Patent Application Laid-Open Publication No. 2005-26384, an inductor element is disclosed which includes a conductor trace substrate, a conductor trace pattern provided on the conductor trace substrate, and a helical coil formed by a plurality of wires that are provided on each of adjacent conductor trace patterns so as to be raised in an arc shape.

### SUMMARY OF THE INVENTION

In recent years, as the field of application of high-frequency circuits is widened, the high-frequency circuits have been increasingly demanded to be reduced in size and manufactured at lower costs. Particularly, in the wireless field, the market tends to demand a so-called one-chip LSI in which base-band to high-frequency analog parts are integrated. Furthermore, at the level of modules, it has been desired to reduce the size of parts and the parts count on the mounting board.

On the other hand, by taking into account, for example, noise and power consumption characteristics, typically used as the inductive element of the VCO is an inductor coil such as an external chip coil. However, use of the inductor coil would be accompanied by an increase in a mounting area. Furthermore, the external inductor coil is expensive when compared with other parts. Thus, this would lead to an increase in parts count or an increase in costs.

As a VCO that is designed to be reduced in parts count, known is one that includes a spiral inductor. The spiral inductor is comprised of conductor traces in a conductor trace layer on the board, and thus requires no additional parts that constitute an inductive element. However, the spiral inductor has a very low Q value when compared with the chip coil because of those factors such as a high conductor trace resistance and loss of signals caused by an eddy current generated on the board. Thus, this would lead to a problem such as an increase in noise or an increase in power consumption.

The present invention was developed in view of the aforementioned points. It is therefore an object of the invention to provide an oscillator which includes an inductive element having a high performance with a reduced number of parts and a phase-locked loop circuit that employs the oscillator.

An oscillator of the present invention comprising: an oscillator circuit element having a substrate terminal group and a capacitance section provided on an element substrate, the substrate terminal group comprising at least three substrate terminals including a first substrate terminal and a second substrate terminal, the capacitance section being connected between the first substrate terminal and the second substrate terminal; a mount part including an external terminal group comprised of at least one external terminal and mounting thereon the oscillator circuit element; a plurality of inductance lines which are formed among the at least three substrate terminals by conductor wirings which connect between the at least three substrate terminals of the substrate terminal group and the at least one external terminal; and a switch circuit provided on the element substrate to control a connection state of the plurality of inductance lines.

### BRIEF DESCRIPTION OF THE DRAWINGS

FIG. 1 is a block diagram illustrating the configuration of a PLL 10 according to a first embodiment;

FIG. 2A is a view illustrating the configuration of a VCO 13, and FIG. 2B is a circuit diagram illustrating an equivalent circuit of an inductance section 23 of the VCO 13;

FIG. 3 is a view illustrating an inductance L and Q value comparisons between the first embodiment and a first comparative example;

FIGS. 4A to 4C are views illustrating the configuration of a PLL 30 of a second embodiment and a VCO 31 in the PLL 30;

FIGS. 5A and 5B are views illustrating the configuration of VCOs 41 and 44 according to modified example-1 and modified example-2 of the second embodiment;

FIGS. 6A and 6B are views illustrating the configuration of a VCO 47 according to a modified example-3 of the second embodiment;

FIGS. 7A and 7B are views illustrating the configuration of a VCO 50 according to modified example-4 of the second embodiment; and

FIG. 8 is a view illustrating the configuration of a VCO 51 according to a third embodiment.

### DETAILED DESCRIPTION OF THE INVENTION

The present invention was developed in view of using external conductor wirings such as bonding wires as an inductive element in an LC circuit of an oscillator such as a voltage controlled oscillator (VCO) as well as enabling the adjustment of inductance. In the following embodiments, descriptions will be made to the case where the VCO is used as the oscillator. Now, the phase-locked loop circuit and the VCO of an embodiment of the present invention will be described in detail below.

### First Embodiment

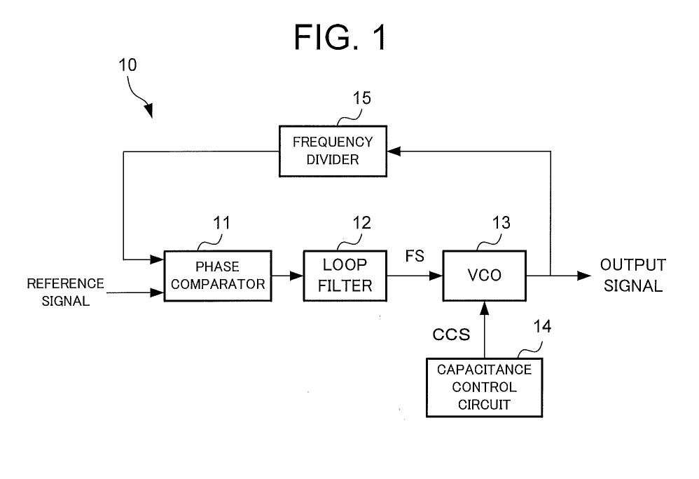

FIG. 1 is an explanatory block diagram illustrating the configuration of a PLL 10 according to a first embodiment of the present invention. The PLL 10 is comprised of a phase comparator 11, a loop filter 12, a VCO 13, a capacitance control circuit 14, and a frequency divider 15. The phase comparator 11 makes a comparison between an input signal (reference signal) and a frequency-divided signal into which the frequency divider 15 has divided an oscillation signal outputted by the VCO 13, and produces a comparison signal in accordance with the phase difference therebetween. The comparison signal produced by the phase comparator 11 is supplied to the loop filter 12. For example, the phase comparator 11 is comprised of a logic circuit and a charge pump (not shown).

The loop filter 12 performs frequency filtering on the comparison signal supplied from the phase comparator 11 to produce a filtered signal FS. The filtered signal FS produced by the loop filter 12 is supplied to the VCO 13. The loop filter 12 is comprised of a low pass filter which interrupts, for example, high-frequency components of signals.

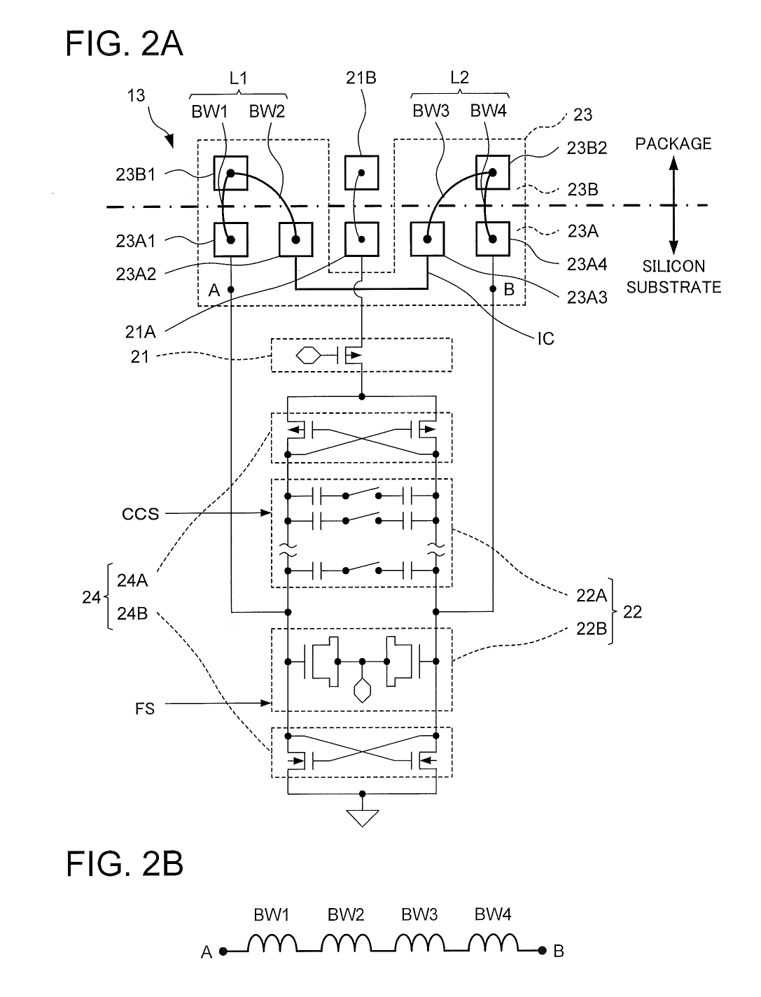

The VCO 13 produces an oscillation signal which has a frequency in accordance with the filtered signal FS supplied from the loop filter 12. The VCO 13 has a capacitance section and an inductance section. The VCO 13 produces oscillation signals that differ in frequency due to a change in the electric capacitance of the capacitance section and/or in the inductance of the inductance section. The oscillation signal from the VCO 13 is delivered to an outside circuit as well as supplied to the frequency divider 15. The detailed configuration of the VCO 13 will be discussed later with reference to FIG. 2.

The capacitance control circuit 14 generates a capacitance control signal CCS which controls the connecting and non-connecting states for each of a plurality of capacitors provided in the capacitance section in the VCO 13, and then supplies the capacitance control signal CCS to the VCO 13. Note that the capacitance control signal CCS may not be supplied by the capacitance control circuit 14 but, for example, may be supplied from outside (not shown) to the VCO 13.

The frequency divider 15 serves to divide the frequency of an input signal. The frequency divider 15 converts an oscillation signal supplied from the VCO 13 into a signal (frequency-divided signal) having the frequency thereof divided by an integer. The frequency-divided signal produced by the frequency divider 15 is supplied to the phase comparator 11.

FIG. 2A is a circuit diagram illustrating the configuration of the VCO 13. Each of the sections surrounded by the broken lines in the figure indicates each portion of the VCO 13. Furthermore, the small filled circles in the figure indicate a connection point. Now, a description will be made to each member of the VCO 13.

The VCO 13 has a current source 21. The current source 21 serves to supply a constant current through the circuits of the VCO 13. For example, the current source 21 is comprised of transistors such as MOSFETs and is connected to a substrate terminal 21A that is a pad terminal formed on the element substrate. The substrate terminal 21A is connected to an external terminal 21B through a bonding wire.

The VCO 13 has a capacitance section 22. The capacitance section 22 has a capacitance coarse adjustment part 22A and a capacitance fine adjustment part 22B which are connected in parallel to each other. The capacitance section 22 is connected between a substrate terminal 23A1 (first substrate terminal) and a substrate terminal 23A4 (second substrate terminal). The capacitance section 22 has a capacitance value (hereafter referred to as the capacitance) C which can be determined by the capacitance of the capacitance coarse adjustment part 22A and the capacitance fine adjustment part 22B.

The capacitance coarse adjustment part 22A is comprised of capacitive switch elements that include a plurality of capacitors and switches. The capacitance coarse adjustment part 22A varies the capacitance thereof by operating the switches in response to the capacitance control signal CCS from the capacitance control circuit 14 so as to switch capacitors to be connected. The capacitance fine adjustment part 22B is comprised of variable capacitance diodes (varactors). The capacitance fine adjustment part 22B varies the capacitance thereof according to the filtered signal FS from the loop filter 12. The capacitance C of the capacitance section 22 varies in accordance with the capacitance control signal CCS from the capacitance control circuit 14 and the filtered signal FS from the loop filter 12.

As shown in FIG. 2A, the VCO 13 includes an inductance section 23 which is connected in parallel to the capacitance section 22. The inductance section 23 includes four substrate terminals (substrate terminals 23A1 to 23A4) that are pad terminals formed on the element substrate, two external terminals (external terminals 23B1 and 23B2), and four bonding wires (bonding wires BW1, BW2, BW3, and BW4). For convenience of explanation below, one end of the inductance section 23 will be referred to as an end portion A, while the other end will be referred to as an end portion B. In addition, the substrate terminals connected to the capacitance section 22, i.e., the substrate terminals 23A1 and 23A4 will be called the first substrate terminal and the second substrate terminal, respectively, while the other substrate terminals, i.e., the substrate terminals 23A2 and 23A3 are called a third substrate terminal. That is, the capacitance section 22 and the inductance section 23 are connected in parallel to each other between the first substrate terminal and the second substrate terminal (i.e., 23A1 and 23A4), while the inductance section 23 is formed through the third substrate terminals (i.e., 23A2 and 23A3) between the first substrate terminal and the second substrate terminal.

The bonding wires BW1 and BW2 form an inductance line L1 between the substrate terminals 23A1 and 23A2. More specifically, the inductance line L1 is comprised of the bonding wires BW1 and BW2 that are connected between the substrate terminal 23A1 and the substrate terminal 23A2 through the external terminal 23B1. In the same manner, there is formed an inductance line L2 between the substrate terminals 23A3 and 23A4. Note that the substrate terminals 23A2 and 23A3 are connected to each other through an intra-substrate conductor trace IC.

As shown in FIG. 2A, the inductance section 23 is configured to lead from the end portion A to the end portion B through a series connection which is formed in the following order by: the substrate terminal 23A1, the bonding wire BW1, the external terminal 23B1, the bonding wire BW2, the substrate terminal 23A2, the intra-substrate conductor trace IC, the substrate terminal 23A3, the bonding wire BW3, the external terminal 23B2, the bonding wire BW4, and the substrate terminal 23A4.

FIG. 2B shows an equivalent circuit of the inductance section 23 between the end portion A and the end portion B. As shown in FIG. 2B, the inductance section 23 has an inductance value (hereafter referred to as the inductance) L which can be determined by the total inductance of the four bonding wires (the two inductance lines L1 and L2). That is, the inductance section 23 is comprised of the bonding wires.

The VCO 13 has an oscillation frequency which is determined according to the resonance frequency of the resonant circuit that includes the capacitance section 22 (the capacitance coarse adjustment part 22A and the capacitance fine adjustment part 22B) and the inductance section 23. Thus, a change in the capacitance C of the capacitance section 22 leads to a change in the frequency of an oscillation signal outputted by the VCO 13.

The VCO 13 includes a negative resistance section 24 that is connected in parallel to the capacitance section 22 and the inductance section 23. The negative resistance section 24 has a first negative resistance part 24A and a second negative resistance part 24B which are connected in parallel to each other. For example, the first negative resistance part 24A includes a pair of P-channel MOSFETs of which gates and drains are cross-connected to each other (in a so-called cross-couple connection). The second negative resistance part 24B includes a pair of N-channel MOSFETs of which gates and drains are also cross-connected to each other. The negative resistance section 24 produces a negative resistance for canceling out the parasitic resistance that is present in the capacitance section 22 (the capacitance coarse adjustment part 22A and the capacitance fine adjustment part 22B) and the inductance section 23.

For example, the external terminals 23B1 and 23B2 of the inductance section 23 and the external terminal 21B of the current source 21 are configured as inner leads of a semiconductor package (hereafter referred to simply as the package) in which the element substrate is mounted. Furthermore, for example, on the element substrate there are formed not only the current source 21 of the VCO 13, the capacitance section 22, and the negative resistance section 24 but also the other components of the PLL 10 such as the phase comparator 11.

As used herein, the member on which the entire VCO 13 including the element substrate and the external terminals are referred to as the mount part. In this embodiment, the mount part comprises the package, so that the external terminal group includes the inner leads of a lead frame provided in the package. Furthermore, of the members that constitute the VCO 13, those that are formed on the element substrate, that is, the current source 21, the capacitance section 22, the substrate terminals 23A1 to 23A4, and the negative resistance section 24 are referred to as an oscillator circuit element (the parts below the alternate long and short dashed line of FIG. 2A.)

Thus, the VCO 13 of this embodiment includes: the oscillator circuit element formed on the element substrate; the mount part on which the oscillator circuit elements are mounted and which has the external terminals; and the plurality of inductance lines formed between the plurality of substrate terminals by bonding wires connecting between the substrate terminals and at least one external terminal. Furthermore, the inductance section 23 is comprised of the substrate terminals on the element substrate; the external terminals on the mount part; and the bonding wires connecting between the substrate terminals and the external terminals.

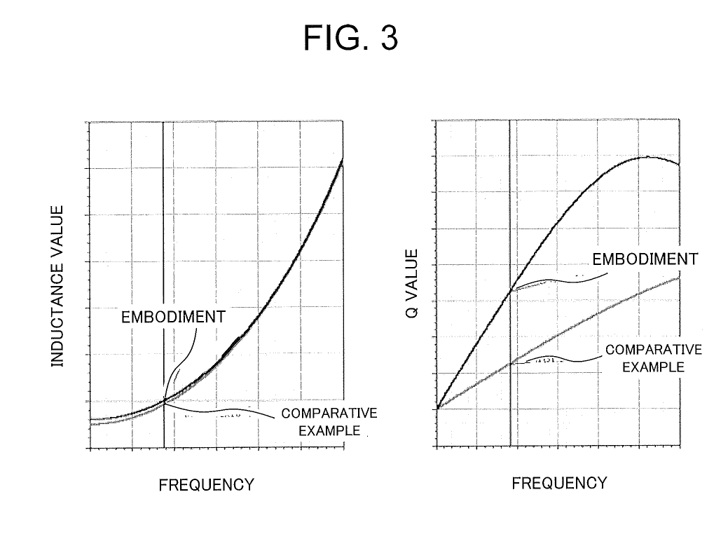

FIG. 3 is a graph showing the inductance L and Q values of the VCO 13. To evaluate the characteristics of the VCO 13, prepared was a comparative example in which the inductance section includes a chip coil. The VCO according to the comparative example is constructed in the same manner as the VCO 13 of the first embodiment except that the inductance section includes the chip coil.

The graph on the left of FIG. 3 shows a comparison of the inductance values between the embodiment and the comparative example. The horizontal axis of the figure represents the frequency and the vertical axis represents the inductance values. As illustrated, the difference in inductance between the embodiment and the comparative example is approximately zero. It can thus be seen that the VCO 13 according to this embodiment achieved the same inductance as that of the chip coil.

The graph on the right of FIG. 3 shows a comparison of the Q values between the embodiment and the comparative example. The horizontal axis of the figure represents the frequency and the vertical axis represents the Q value. As illustrated, it can be seen that the VCO 13 of the embodiment has a Q value higher than that of the VCO of the comparative example. It can also be seen that a partial region has a Q value about twice as much. It can thus be seen that the VCO 13 according to this embodiment has outputted an oscillation signal having a Q value that was higher than that of the chip coil.

In this embodiment, the inductance section 23 is comprised of bonding wires. Thus, when compared with the case where the chip coil is employed as an inductive element, it is possible to reduce a mounting area. It is thus possible to reduce the sizes of the oscillator circuit element and the package. Furthermore, since the chip coil is not used, the parts count can be reduced. It is also possible to form an inductance section that has the same or higher characteristics as those of the chip coil. Furthermore, the VCO according to this embodiment has the capacitance coarse adjustment part that includes capacitors and the capacitance fine adjustment part that includes varactors. It is thus possible to precisely adjust (control) the frequency of the oscillation signal that is outputted from the VCO (the PLL).

Note that in this embodiment, a description was made to the case where the two inductance lines constitute the inductance section. However, the number of inductance lines is not limited thereto. A description was also made to the case where the inductance lines are formed of bonding wire. However, the inductance line is not limited to the bonding wire so long as the line is an inductive conductor trace or wiring.

### Second Embodiment

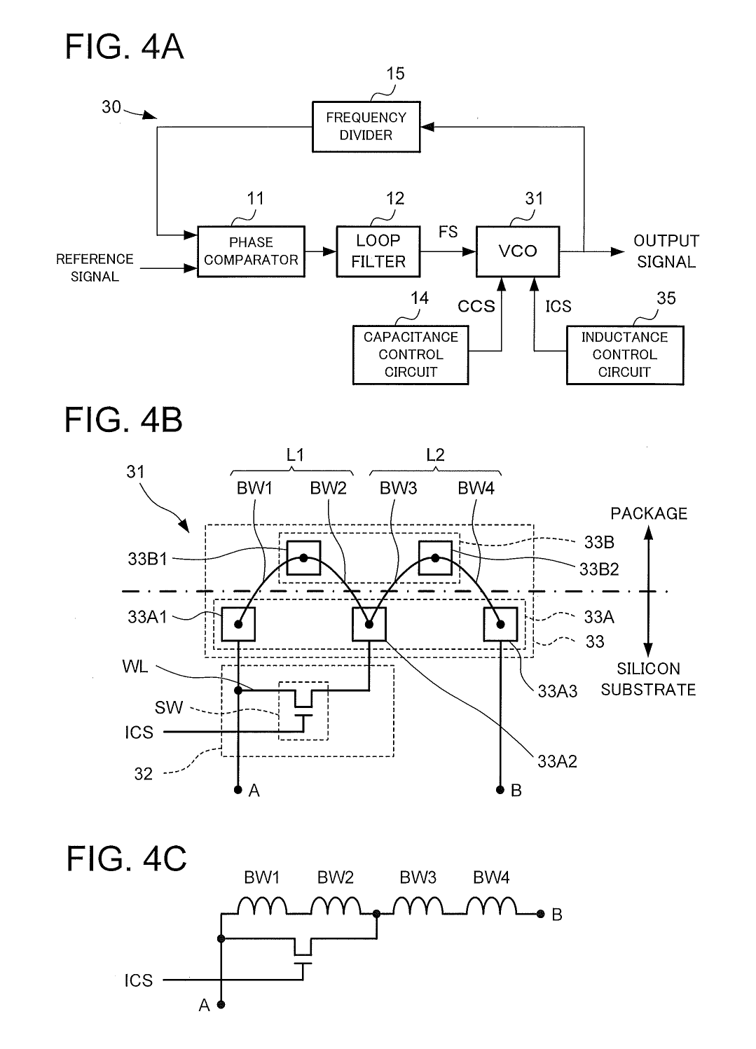

FIG. 4A is a block diagram illustrating the configuration of a PLL 30 according to a second embodiment. The PLL 30 includes the phase comparator 11, the loop filter 12, and the frequency divider 15 which are constructed in the same manner as in the PLL 10. The PLL 30 includes a VCO 31 for outputting oscillation signals that have different frequencies in accordance with the filtered signal FS from the loop filter 12, the capacitance control signal CCS from the capacitance control circuit 14, and an inductance control signal ICS from an inductance control circuit 35. The oscillation signal that the VCO 31 outputs is delivered to outside and supplied to the frequency divider 15.

FIG. 4B is a circuit diagram illustrating the configuration of the VCO 31 of the PLL 30. The VCO 31 is constructed in the same manner as the VCO 13 except that the VCO 31 has a switch circuit 32. For clarity and ease of understanding of the figure, FIG. 4B indicates only the switch circuit 32 and an inductance section 33 (i.e., the portion between the end portion A and the end portion B.)

The VCO 31 includes the inductance section 33 with two inductance lines that have four bonding wires. The inductance section 33 includes a substrate terminal group 33A that includes three substrate terminals 33A1 to 33A3, an external terminal group 33B that includes two external terminals 33B1 and 33B2, and four bonding wires BW1 to BW4 that are connected in series between the end portions A and B via each of the substrate terminals and each of the external terminals.

As shown in FIG. 4B, the substrate terminal group 33A is constructed such that the substrate terminals 33A1 to 33A3 are aligned in a linear array. Furthermore, the external terminal group 33B is constructed such that the external terminals 33B1 and 33B2 are aligned in a linear array. Furthermore, the substrate terminal group 33A is disposed to oppose to the external terminal group 33B.

The bonding wires BW1 to BW4 are connected in series between the first substrate terminal 33A1 and the second substrate terminal 33A3. Furthermore, the two bonding wires BW1 and BW2 form one inductance line L1 between the substrate terminal 33A1 and substrate terminal 33A2. More specifically, the inductance line L1 is comprised of the bonding wires that are connected between the substrate terminals 33A1 and 33A2 via the external terminal 33B1. In the same manner, between the substrate terminals 33A2 and 33A3 there is formed the inductance line L2 that includes the two bonding wires BW3 and BW4 connected via the external terminal 33B2. That is, the two inductance lines L1 and L2 are connected in series between the first substrate terminal 23A1 and the second substrate terminal 23A3.

In this embodiment, the bonding wires (inductance lines) are connected in series from the end portion A to the end portion B through the substrate terminal 33A1 (the first substrate terminal), the external terminal 33B1, the substrate terminal 33A2, the external terminal 33B2, and the substrate terminal 33A3 (the second substrate terminal).

The VCO 31 includes the switch circuit 32 that varies the inductance L of the inductance section 33. The switch circuit 32 serves to short-circuit the inductance line L1. The switch circuit 32 has a switch element SW that is connected between the substrate terminals (the substrate terminals 33A1 and 33A2) to which the inductance line L1 is connected.

The VCO 31 includes the inductance control circuit 35 for controlling the conducting and non-conducting states of the switch element SW. The inductance control circuit 35 produces the inductance control signal ICS for switching the conducting and non-conducting states of the switch element SW. The switch circuit 32 and the inductance control circuit 35 are formed, for example, on the element substrate (silicon substrate.)

The switch circuit 32 has the switch element SW which is connected in parallel to the inductance line L1 between the two substrate terminals 33A1 and 33A2 and which switches the conducting and non-conducting states between the substrate terminals 33A1 and 33A2. For example, it is possible to employ, as the switch element SW, a transistor such as MOSFETs or bipolar transistors.

FIG. 4C shows an equivalent circuit of the switch circuit 32 and the inductance section 33 of the VCO 31. As shown in FIG. 4C, the switch element SW can switch the number of inductance lines connected within the inductance section (i.e., the length of bonding wire). For example, when the switch element SW is not conducting, between the substrate terminals 33A1 and 33A3 are connected all the bonding wires BW1 to BW4 of the inductance section 33. Thus, the inductance L of the inductance section 33 is provided by the inductance lines L1 and L2 connected in series.

On the other hand, when the switch element SW is conducting, the bonding wires BW1 and BW2 (i.e., the inductance line L1) are short-circuited. Thus, between the substrate terminals 33A1 and 33A3 are connected the bonding wires BW3 and BW4. Thus, the inductance L of the inductance section 33 is provided only by the inductance line L2.

In the embodiment, the switch circuit makes it possible to select or switch the inductance lines that constitute the inductance section. That is, the connection state of the inductance lines can be controlled by the switch circuit. Thus, the inductance L of the inductance section, that is, the oscillation frequency band can be switched within the same circuit.

Furthermore, as with the first embodiment, it is also possible in this embodiment that the filtered signal FS from the loop filter 12 and the capacitance control signal CCS from the capacitance control circuit 14 can be used to control the capacitance of the capacitance section 22. Thus, in this embodiment, it is possible to employ the inductance control signal ICS from the inductance control circuit 35 to adjust the frequency band, the capacitance control signal CCS from the capacitance control circuit 14 to make a coarse adjustment to the frequency, and the filtered signal FS from the loop filter 12 to make a fine adjustment to the frequency. It is thus possible to provide wider-band and multi-band control by the VCO (PLL) in the same circuit. As a matter of course, this contributes to reduction in the size of the element and package.

Note that in this embodiment, a description was made to the case where the three substrate terminals, the two external terminals, and the four bonding wires (two inductance lines) constitute the inductance section. However, the number of each member is not limited thereto. For example, five substrate terminals, four external terminals, and eight bonding wires may also be employed to constitute the inductance section. Or alternatively, a greater number of members may also be used to constitute the inductance section.

Furthermore, in this embodiment, a description was made to the case where one switch element constitutes the switch circuit. However, the number of switch elements is not limited thereto. For example, it is also possible to employ a plurality of switch elements to constitute the switch circuit.

Furthermore, in this embodiment, since a description was made to the case where the three substrate terminals are used, one of the substrate terminals to which the switch circuit is connected is the substrate terminal (the first substrate terminal) that constitutes an end portion of the inductance section. However, the substrate terminal to which the switch circuit is connected needs not to be the substrate terminal that constitutes an end portion of the inductance section. The switch circuit may only have to be connected between any two substrate terminals.

Furthermore, a description was made to the case where the VCO has the inductance control circuit for controlling the conducting and non-conducting states of the switch element of the switch circuit. However, the control provided by the switch circuit is not limited thereto. For example, the switch circuit may have a switch element connected between substrate terminals connected to an inductance line, and the VCO may have an input part (not shown) for inputting an inductance control signal to control the conducting and non-conducting states of the switch element. That is, the conducting and non-conducting states of the switch element may be controlled not by the inductance control circuit but by the input part outside the element substrate.

Furthermore, a description was made to the case where one inductance control signal is used to switch one switch element of the switch circuit. However, the number of the inductance control signals as well as the number of switch elements to be connected or controlled is not limited thereto. For example, the switch circuit may have two switch elements, so that the inductance control circuit employs one inductance control signal to control the conducting and non-conducting states of the two switch elements at the same time. Furthermore, two inductance control signals may also be employed to provide independent control to the two switch elements.

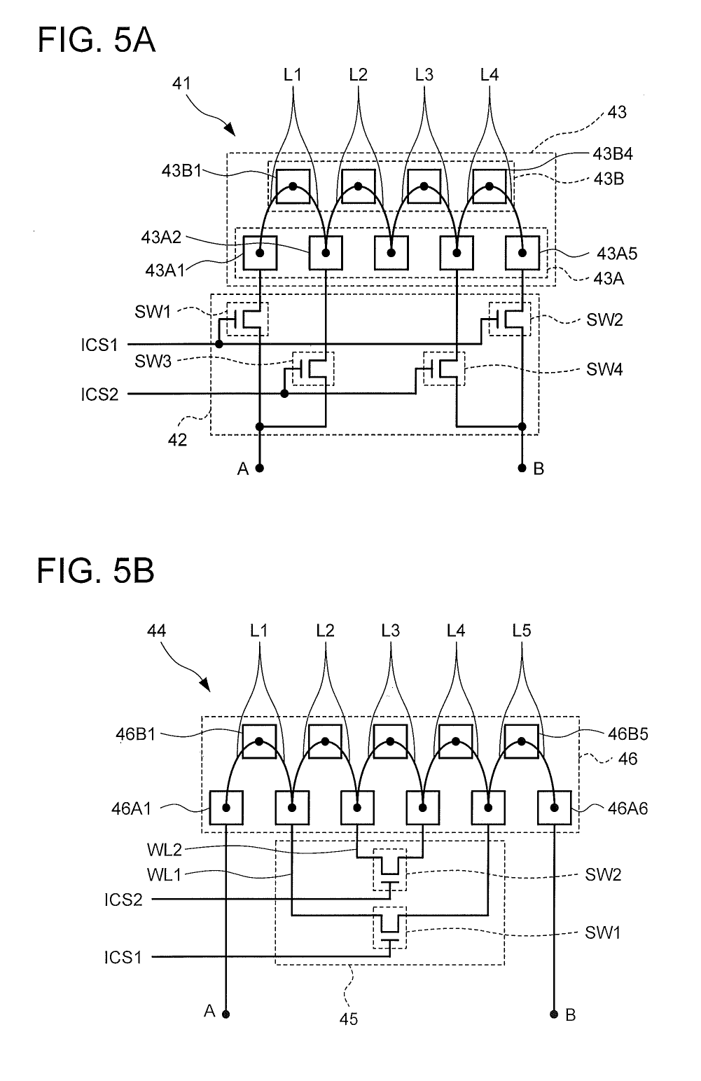

FIG. 5A is an explanatory circuit diagram illustrating the configuration of a VCO 41 according to a modified example-1 of the second embodiment. The VCO 41 is constructed in the same manner as the VCO 31 except the configuration of the switch circuit and the inductance section. The VCO 41 comprises an inductance section 43 including four inductance lines (eight bonding wires) and a switch circuit 42 including four switch elements.

The inductance section 43 has a substrate terminal group 43A that includes five substrate terminals (substrate terminals 43A1 to 43A5), an external terminal group 43B that includes four external terminals (external terminals 43B1 to 43B4), and four inductance lines L1 to L4 formed by eight bonding wires that are connected in series between the first substrate terminal 43A1 and the second substrate terminal 43A5 via the respective substrate terminals and external terminals.

The switch circuit 42 includes four switch elements SW1 to SW4 that are configured to short-circuit the inductance lines L1 and L4. The switch circuit 42 switches the conducting and non-conducting states of the switch elements SW1 to SW4 by two inductance control signals ICS1 and ICS2.

When the inductance control signal ICS1 is supplied, that is, when the switch elements SW1 and SW2 are conducting, the inductance L of the inductance section 43 is provided by the inductance lines L1 to L4. On the other hand, when the inductance control signal ICS2 is supplied, that is, when the switch elements SW3 and SW4 are conducting, the inductance lines L1 and L4 are short-circuited, so that the inductance L of the inductance section 43 is provided by the inductance lines L2 and L3.

FIG. 5B is an explanatory circuit diagram illustrating the configuration of a VCO 44 according to a modified example-2 of the second embodiment. The VCO 44 is constructed in the same manner as the VCO 31 except the configuration of the switch circuit and the inductance section. The VCO 44 comprises an inductance section 46 including five inductance lines (ten bonding wires) and a switch circuit 45 including two switch elements.

The inductance section 46 has six substrate terminals (substrate terminals 46A1 to 46A6), five external terminals (external terminals 46B1 to 46B4), and five inductance lines (the inductance lines L1 to L5) formed by ten bonding wires that are connected in series between the first substrate terminal 46A1 and the second substrate terminal 46A6 via the respective substrate terminals and external terminals.

The switch circuit 45 includes the switch element SW1 that is configured to short-circuit the inductance lines L2 to L4 and the switch element SW2 that is configured to short-circuit the inductance line L3. As shown in FIG. 5B, the switch circuit 45 switches the conducting and non-conducting states of the switch element SW1 and the switch element SW2 by the inductance control signals ICS1 and ICS2, respectively.

In the aforementioned modified example-1 and modified example-2, the inductance line being short-circuited can be controlled in detail, so that the inductance L and in turn the frequency can be controlled with high degree of flexibility.

Note that the number of switches is preferably reduced by taking into account the inductance characteristics. This is because the less the number of switches, the less the resistance of the switches can be, whereby the inductance L is less affected. Furthermore, reduction in the number of switches allows reduction in size.

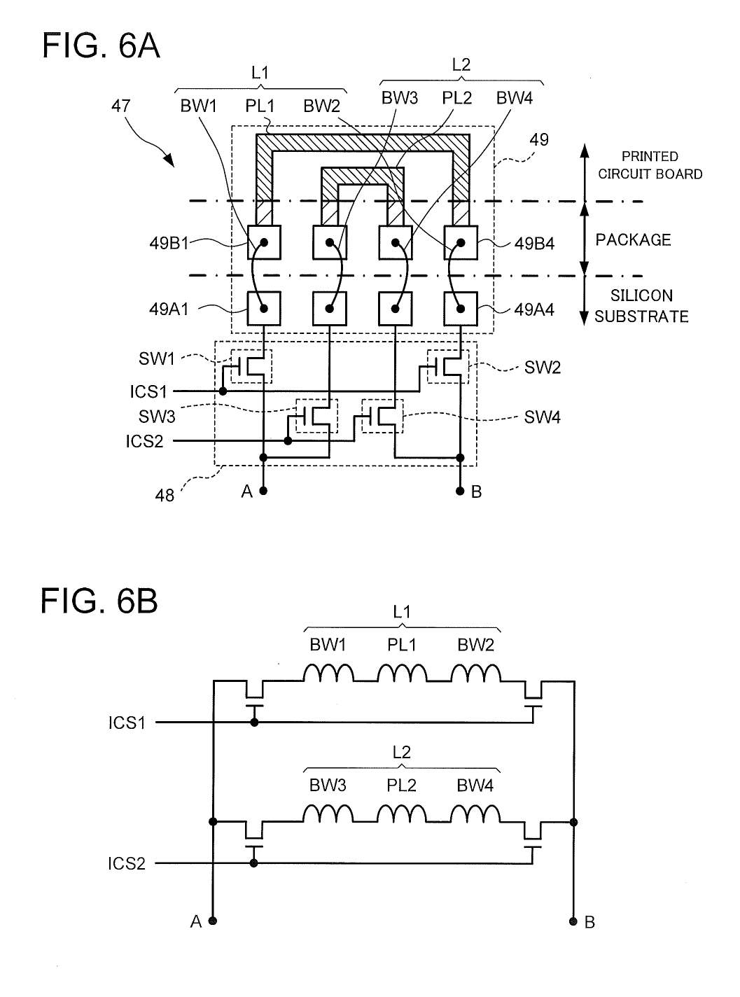

FIG. 6A is a view illustrating the configuration of a VCO 47 according to a modified example-3 of the second embodiment. The VCO 47 is constructed in the same manner as the VCO 31 except the configurations of a switch circuit 48 and an inductance section 49. The inductance section 49 of the VCO 47 is comprised of a conductor trace that includes PCB conductor traces provided on the printed circuit board (PCB).

The inductance section 49 comprises four substrate terminals 49A1 to 49A4; four external terminals 49B1 to 49B4; and two inductance lines L1 and L2 formed by four bonding wires, which are connected in parallel between the first substrate terminal 49A1 and the second substrate terminal 49A4, and two PCB conductor traces. The conductor wirings forming the inductance lines are connected to the PCB conductor traces on the printed circuit board (PCB).

The inductance line L1 is comprised of a bonding wire BW1 connecting between the first substrate terminal 49A1 and the external terminal 49B1; a PCB conductor trace PL1 connecting between the external terminal 49B1 and the external terminal 49B4; and a bonding wire BW2 connecting between the external terminal 49B4 and the second substrate terminal 49A4. Between the bonding wires and the PCB conductor traces are disposed the leads that connect between the external terminals on the package and the conductor trace terminals (not shown) on the printed circuit board. In the same manner, the inductance line L2 is comprised of the bonding wires BW3 and BW4; and a PCB conductor trace PL2 connecting between the bonding wires through the printed circuit board.

The switch circuit 48 includes switch elements SW1 to SW4 that are configured to select and allow either one of the inductance lines L1 and L2 to conduct. The conducting and non-conducting states of the switch elements SW1 to SW4 are switched by the inductance control signals ICS1 and ICS2.

FIG. 6B illustrates the equivalent circuit of the switch circuit 48 and the inductance section 49 of the VCO 47. As illustrated in FIG. 6B, when the inductance control signal ICS1 has been supplied and the switch elements SW1 and SW2 are conducting, between the first and second substrate terminals there is connected the inductance line L1. On the other hand, when the inductance control signal ICS2 has been supplied and the switch elements SW3 and SW4 are conducting, between the first and second substrate terminals there is connected the inductance line L2.

In this modified example, the inductance lines are comprised of not only bonding wires but also the PCB conductor traces on the printed circuit board. The PCB conductor traces can be configured to have the length and width that are precisely determined when compared with the bonding wires. It is thus possible to achieve accurate inductance lines and inductance L with high degree of flexibility.

Note that in this modified example, the VCO 47 is formed across the element substrate, the package, and the printed circuit board outside the package. Thus, the mount part on which the oscillator circuit element (the members constituting the VCO except the external terminal group, the bonding wires, and the PCB conductor traces) is mounted includes the inner leads of the package and the printed circuit board.

Furthermore, in this modified example, the inductance lines are comprised of the PCB conductor traces. As used herein, the entire conductor trace constituting the inductance lines including the bonding wires and the PCB conductor traces will be referred to simply as the conductor wiring.

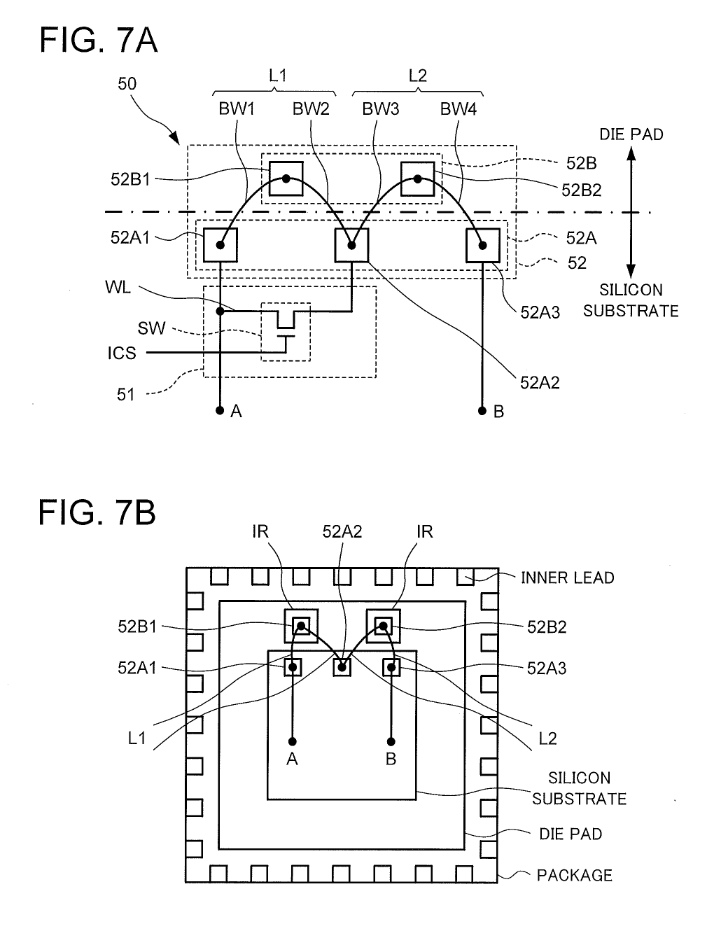

FIG. 7A is an explanatory view illustrating the configuration of a VCO 50 according to a modified example-4 of the second embodiment. The VCO 50 is constructed in the same manner as the VCO 31 except the configuration of an inductance section 52. There are provided a switch circuit 51 and a substrate terminal group 52A which are formed in the same manner as the switch circuit 32 and the substrate terminal group 33A of the VCO 31.

The inductance section 52 is comprised of terminals as the substrate terminal group 52A on a silicon substrate; conductive terminals provided as an external terminal group 52B on die pads; and inductance lines L1 and L2 which are comprised of bonding wires BW1 to BW4 connected between the substrate terminal group 52A and the external terminal group 52B. For example, the die pad may be an electrical conductor which is connected to a grounded lead (not shown) and secures the silicon substrate within the package.

FIG. 7B is a top view illustrating the package, the die pads, and the silicon substrate, including the oscillator with the VCO 50 of this modified example. For the sake of clarity of the figure, the figure shows only the inductance section 52 of the VCO 50 with the other members such as the switch circuit 51 eliminated. Furthermore, for purposes of illustration, the figure shows the inner leads that are provided within the package. In this modified example, a description will be made to the case where the oscillator is constructed in a quad flat non-leaded (QFN) package. As shown in FIG. 7B, the inductance section 52 of the VCO 50 is constructed without using the inner leads of the package.

The external terminals 52B1 and 52B2 (the external terminal group 52B) of the VCO 50 are formed as a conductive terminal provided on the die pads. More specifically, the die pads are provided with an insulating region IR and a conductive material is formed within the insulating region IR, thereby forming the external terminals 52B1 and 52B2. The inductance lines L1 and L2 are comprised of bonding wires that are connected, via the external terminals 52B1 and 52B2, between the first substrate terminal 52A1 and the second substrate terminal 52A3.

In this modified example, the mount part which has the external terminals and on which the oscillator circuit element is mounted includes the die pads. On the other hand, the inductance line is comprised of the conductor trace that is formed of a bonding wire. That is, the mount part is formed of the die pads, and the conductor trace constituting the inductance line is formed of the bonding wire.

This modified example has an advantage of being capable of constituting an inductance line without using the inner leads of the package. This in turn allows for employing the inner leads for other conductor wirings, thereby providing higher degree of flexibility in design. Furthermore, the inductance L will not be exerted by external influence via the inner leads and can thus be set to an exact value.

Note that in this modified example, a description was made to the case where the inductance line is formed between adjacent substrate terminals via external terminals. However, the external terminals may also be connected to each other by a bonding wire so as to form the inductance line between the substrate terminals. It is also possible to provide a conductive terminal as an external terminal, for example, linearly on die pads, so that each of the linear ends is connected to a substrate terminal. That is, it is also possible to construct the inductance line not only by the bonding wires between the substrate terminal (conductive terminal) and the external terminal but also by the conductor traces on the conductive terminals on the die pads. It is thus possible to achieve a still higher degree of flexibility in the design of the inductance L.

### Third Embodiment

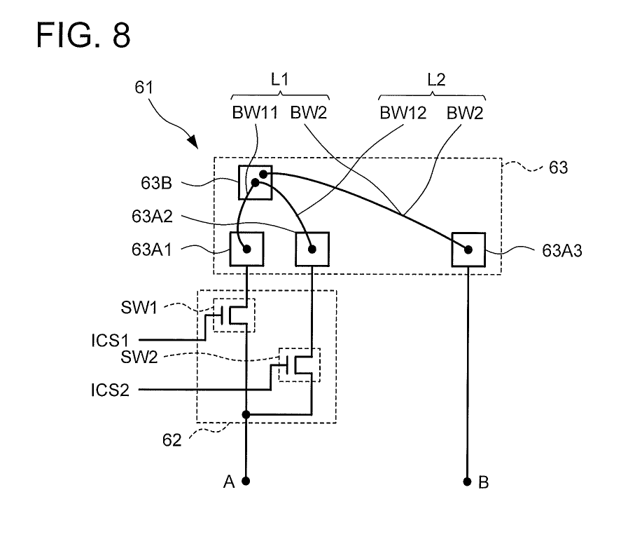

FIG. 8 is an explanatory circuit diagram illustrating the configuration of a VCO 61 according to a third embodiment. The VCO 61 is constructed in the same manner as the VCO 13 except the configurations of an inductance section and a switch circuit. For the sake of clarity of the figure, the figure shows only a switch circuit 62 and an inductance section 63.

The inductance section 63 is comprised of three substrate terminals 63A1 to 63A3, one external terminal 63B, and three bonding wires BW11, BW12, and BW2 connecting between each of the substrate terminals and the external terminal 63B.

The inductance section 63 includes an inductance line L1 connected between the substrate terminals 63A1 and 63A3 and an inductance line L2 connected between the substrate terminals 63A2 and 63A3. The inductance lines L1 and L2 are connected in parallel to each other between the external terminal 63B (a common terminal) and the substrate terminals 63A1 to 63A3 with the external terminal 63B employed as the common terminal.

More specifically, the inductance section 63 includes the bonding wires BW11 and BW12 that connect between each of the substrate terminals 63A1 and 63A2 and the external terminal 63B (the common terminal), and the bonding wire BW2 that connects between the common terminal and the other substrate terminal, i.e., the substrate terminal 63A3.

The VCO 61 comprises the switch circuit 62 that selects an inductance line and makes the line conducting. The switch circuit 62 makes conducting either one of the inductance lines L1 and L2, which are connected in parallel to each other, and makes non-conducting the other (i.e., selects either one of the inductance lines L1 and L2 and allows the line to be conducting.)

The switch circuit 62 includes switch elements SW1 and SW2 that make either the inductance lines L1 or L2 conducting. The switching of conducting and non-conducting states of the switch elements SW1 and SW2 is controlled by the inductance control signals ICS1 and ICS2. Specifically, when only the switch element SW1 is conducting (SW2: non-conducting), between the substrate terminals 63A1 to 63A3 is conducting, and the inductance L of the inductance section 63 is provided by the inductance line L1. On the other hand, when only the switch element SW2 is conducting (SW1: non-conducting), between the substrate terminals 63A2 to 63A3 is conducting, and the inductance L of the inductance section 63 is provided by the inductance line L2.

The bonding wire typically has an inductance L with considerable manufacturing variations because it is difficult to form a bonding wire in a desired length. Thus, strictly speaking, it is difficult to manufacture a bonding wire that has a desired inductance L. In this embodiment, wire is bonded from different substrate terminals to one common terminal, thereby forming a plurality of bonding wires having lengths that are slightly different from each other. From those bonding wires having different lengths, the bonding wire that has the desired inductance L is selected and allowed to be conducting, thereby making fine adjustments to the inductance L. It is thus possible to prevent an influence on the inductance L that may be caused by manufacturing variations of the bonding wires.

The common terminal 63B of the inductance section 63 is connected to the substrate terminal 63A3 via the bonding wire BW2. In this embodiment, an inductance line having a slightly different length (inductance L) is selected and allowed to be conducting, thereby making it possible to provide fine adjustments to the inductance L of the inductance section 63. It is thus possible to provide fine adjustments to the frequency of the oscillation signal of the VCO 61.

Note that in this embodiment, a description was made to the case where either one of the two inductance lines is selected. However, inductance lines to be selected are not limited thereto. For example, when a larger number of substrate terminals are connected to the common terminal, it is possible to provide more precise fine adjustments to the inductance L.

Furthermore, this embodiment can also be implemented by the aforementioned first and second embodiments in combination. For example, when the second embodiment and the third embodiment are combined, it is possible to vary the inductance L of the inductance section, that is, to vary the frequency band of the VCO and make fine adjustments thereto.

In the foregoing, the VCO includes an oscillator circuit element which has a substrate terminal group and a capacitance section and which is provided on an element substrate, the substrate terminal group comprising at least three substrate terminals including a first substrate terminal and a second substrate terminal, the capacitance section being connected between the first substrate terminal and the second substrate terminal; a mount part including an external terminal group comprised of at least one external terminal and on which the oscillator circuit element is mounted; a plurality of inductance lines formed among the at least three substrate terminals by conductor wirings which connect between the at least three substrate terminals and the at least one external terminal; and a switch circuit which is provided on the element substrate and controls the connection state of the plurality of inductance lines. It is thus possible to provide a compact oscillator which has high inductance characteristics such as an inductance L and a Q value and which is reduced in parts count. It is also possible to provide a high-performance PLL.

Note that descriptions were made above to the cases where the VCO is used as the oscillator and to the oscillator employed in the PLL. However, the present invention is applicable to any oscillator that employs the LC circuit.

This application is based on a Japanese Patent application No. 2013-138945 which is hereby incorporated by reference.

What is claimed is:

1. An oscillator comprising:
an oscillator circuit element having a substrate terminal group and a capacitance section provided on an element substrate, the substrate terminal group comprising at least three substrate terminals including a first substrate terminal and a second substrate terminal, the capacitance section being connected between the first substrate terminal and the second substrate terminal;
a mount part including an external terminal group comprised of at least one external terminal and mounting thereon the oscillator circuit element;
a plurality of inductance lines which are formed among the at least three substrate terminals by conductor wirings which connect between the at least three substrate terminals of the substrate terminal group and the at least one external terminal; and
a switch circuit provided on the element substrate to control a connection state of the plurality of inductance lines.

2. The oscillator according to claim 1, wherein the plurality of inductance lines are connected in series between the first substrate terminal and the second substrate terminal.

3. The oscillator according to claim 1, wherein the plurality of inductance lines are connected in parallel between the first substrate terminal and the second substrate terminal.

4. The oscillator according to claim 1, wherein the plurality of inductance, lines are formed by being connected in parallel between a common terminal and the at least three substrate terminals, the common terminal being the one external terminal of the external terminal group; and
the switch circuit allows any one of the plurality of inductance lines connected in parallel to be conducting and makes non-conducting the other inductance lines.

5. The oscillator according to claim 1, wherein the conductor wirings include a conductor wiring implemented by a bonding wire.

6. The oscillator according to claim 1, wherein the mount part includes a semiconductor package, and the external terminal group is comprised of an inner lead of a lead frame provided inside the semiconductor package.

7. The oscillator according to claim 1, wherein the mount part includes a printed circuit board (PCB), and the conductor wirings are connected to a PCB conductor trace of the printed circuit board.

8. The oscillator according to claim 1, wherein the mount part includes a die pad.

9. The oscillator according to claim 1, wherein the switch circuit includes at least one switch element connected between both substrate terminals to which the plurality of inductance lines are connected; and
the oscillator includes an inductance control circuit for controlling conducting and non-conducting states of the at least one switch element.

10. The oscillator according to claim 1, wherein the switch circuit has at least one switch element connected between both substrate terminals to which the plurality of inductance lines are connected; and
the oscillator includes an input part for supplying an inductance control signal for controlling conducting and non-conducting states of the at least one switch element.

11. A phase-locked loop circuit comprising:
a phase comparator for making a phase comparison between a reference signal and a frequency-divided signal to produce a comparison signal;
a filter for producing a filtered signal by frequency-filtering of the comparison signal;
the oscillator according to claim 1 for producing an oscillation signal of the oscillator circuit element on the basis of the filtered signal; and
a frequency divider for producing the frequency-divided signal by frequency division of the oscillation signal.
